(19) United States
(12) Patent Application Publication
(10) Pub. No.: US 2026/0259287 A1
(43) Pub. Date: Sep. 3, 2026

(54) DUAL RESONATOR STRUCTURE FOR NUCLEAR MAGNETIC RESONANCE (NMR) SPECTROSCOPY

(71) Applicants: WISCONSIN ALUMNI RESEARCH FOUNDATION, MADISON, WI (US); Phoenix NMR, LOVELAND, CO (US)

(72) Inventors: Chad RIENSTRA, SUN PRAIRIE, WI (US); Lauren PRICE, MADISON, WI (US); Collin BORCIK, MADISON, WI (US); John STRINGER, LOVELAND, CO (US); Marcus TUTTLE, LOVELAND, CO (US)

(21) Appl. No.: 19/552,548

(22) Filed: Feb. 27, 2026

Related U.S. Application Data
(60) Provisional application No. 63/764,907, filed on Feb. 28, 2025.

(51) Int. Cl. G01R 33/36; G01R 33/34

(52) U.S. Cl. CPC G01R 33/3635; G01R 33/34007; G01R 33/34053; G01R 33/34069; G01R 33/34092

(57) ABSTRACT

A dual resonator structure for a nuclear magnetic resonance probe includes an inner coil having a solenoid coil and an outer coil having a saddle coil. The inner coil is configured to tune a first channel to a first frequency and the outer coil is configured to tune X and Y channels to second and third frequencies independent from and simultaneously with the first frequency. The outer coil is radially spaced from the inner coil. The outer coil and the inner coil are configured to produce orthogonal magnetic fields.

### CROSS REFERENCE TO RELATED APPLICATIONS

This application claims the benefit of priority to U.S. Provisional Application Ser. No. 63/764,907, filed Feb. 28, 2025, the entire contents of which are hereby incorporated by reference herein.

### STATEMENT OF GOVERNMENT RIGHTS

This invention was made with government support under 1946970 awarded by the National Science Foundation and under GM136463 awarded by the National Institutes of Health. The government has certain rights in the invention.

### BACKGROUND

Solid-state NMR (SSNMR) spectroscopy is a technique for characterizing the atomic level structure in materials, including powders, single crystals, frozen glasses, amorphous samples, and tissues. Compared to solution-state NMR, SSNMR spectra have traditionally been characterized by larger linewidths that are useful in obtaining quantitative information on the molecular structure, conformation, and dynamics of the sample. In some cases, SSNMR may be combined with magic angle spinning (MAS) to remove anisotropic interactions and improve the resolution as well as the sensitivity of the technique. While the benefits of MAS have shown promise in SSNMR nearing parity with solution-state NMR, challenges have remained.

### SUMMARY

In accordance with some embodiments of the present disclosure, a dual resonator structure for a nuclear magnetic resonance (NMR) probe is disclosed. The dual resonator structure includes an inner coil comprising a solenoid coil and an outer coil comprising a saddle coil. The inner coil is configured to tune a first channel to a first frequency, the outer coil is configured to tune X and Y channels to second and third frequencies independent from and simultaneously with the first frequency, the outer coil is radially spaced from the inner coil, and the outer coil and the inner coil are configured to produce orthogonal magnetic fields.

In accordance with some other embodiments of the present disclosure, a nuclear magnetic resonance (NMR) probe is disclosed. The NMR probe includes a dual resonator structure disposed at a distal end of the NMR probe, the dual resonator structure having an inner coil comprising a solenoid coil and an outer coil comprising a saddle coil. The inner coil is configured to tune a first channel to a first frequency, the outer coil is configured to tune X and Y channels to second and third frequencies independent from and simultaneously with the first frequency, the outer coil is radially spaced from the inner coil, and the outer coil and the inner coil are configured to produce orthogonal magnetic fields.

In accordance with some embodiments of the present disclosure, a dual resonator structure for a nuclear magnetic resonance (NMR) probe is disclosed. The dual resonator structure includes an inner coil comprising a solenoid coil and an outer coil comprising a saddle coil. The inner coil is configured to tune a first channel to a first frequency of approximately 550 MHz and the outer coil is radially spaced from the inner coil.

In accordance with some embodiments of the present disclosure, the herein disclosed subject matter is also directed to a plug-in module for a nuclear magnetic resonance (NMR) probe, the plug-in module comprising: a circuit board substrate; a plurality of capacitors fixed to the circuit board substrate, the capacitors forming a tuning circuit that cooperates with a solenoid of a resonator structure of the NMR probe to form a resonant circuit associated with operation of the NMR probe; a plurality of conductive receptacles configured to conductively couple with a plug-in board that is mechanically coupled to the NMR probe and that is conductively coupled to the resonator structure and to a transceiver; and a plurality of plate conductor interconnects configured to provide electrical connectivity between the capacitors and the conductive receptacles in a predefined arrangement of the tuning circuit.

In accordance with some embodiments of the present disclosure, the herein disclosed subject matter is also directed to a method for tuning a resonator structure for a nuclear magnetic resonance (NMR) probe, the method comprising: fabricating a plurality of plug-in modules, each of the plug-in modules comprising a set of capacitors mounted to the respective one of the plug-in modules to form a respective tuning circuit, the set of capacitors of each of the plug-in modules having a different respective set of capacitance values to achieve a different respective operating resonant frequency of a resonator structure of the NMR probe; determining a desired operating resonant frequency of the resonator structure of the NMR probe for conducting a given NMR experiment; selecting one of the plurality of plug-in modules suitable to achieve the desired operating resonant frequency based on set capacitance values of the respective set of capacitors mounted on the respective plug-in module configured to achieve the desired operating resonant frequency; plugging the selected one of the plug-in modules into a plug-in board that is mounted to the NMR probe via conductive receptacles of the selected one of the plug-in modules and respective conductors of the plug-in board to provide electrical connectivity between the tuning circuit associated with the capacitors and the resonator structure to form a resonator circuit; and providing a radio frequency (RF) signal through the resonator circuit.

In accordance with other embodiments of the present disclosure, the herein disclosed subject matter is also directed to a nuclear magnetic resonance (NMR) probe system comprising: an NMR probe comprising a resonator structure; a radio frequency (RF) transceiver configured to generate a tuning signal; and a plug-in board coupled to the NMR probe, the plug-in board comprising a plurality of conductors that are wired respectively to the resonator structure and to the RF transceiver, the conductors being configured to receive an electrical connection of conductive receptacles associated with a plug-in module comprising a plurality of capacitors configured to form a tuning circuit, such that mechanical plug-in of the conductors of the plug-in board with the conductive receptacles of the plug-in module provides electrical connectivity between the tuning circuit and the resonator structure to form a resonator circuit with respect to the tuning signal.

Other principal features of the disclosed subject matter will become apparent to those skilled in the art upon review of the following drawings, the detailed description, and the appended claims.

### BRIEF DESCRIPTION OF THE DRAWINGS

Illustrative embodiments of the disclosed subject matter will hereafter be described referring to the accompanying drawings, wherein like numerals denote like elements.

FIG. 1 shows a schematic example of an NMR spectrometer setup, in accordance with some embodiments of the present disclosure.

FIG. 2A shows an example cutaway portion of a probe having a dual resonator structure installed therein for use in the NMR spectrometer of FIG. 1, in accordance with some embodiments of the present disclosure.

FIG. 2B shows another example cutaway portion of the probe of FIG. 2A showing a plurality of capacitors that are connected to the dual resonator structure, in accordance with some embodiments of the present disclosure.

FIG. 2C shows opposing views of the NMR probe of FIG. 2A, in accordance with some embodiments of the present disclosure.

FIG. 2D shows a perspective view of the NMR probe of FIG. 2A, in accordance with some embodiments of the present disclosure.

FIG. 3A shows a perspective view of the dual resonator structure of FIG. 2A, in accordance with some embodiments of the present disclosure.

FIG. 3B shows a front or back view of the dual resonator structure of FIG. 2A, in accordance with some embodiments of the present disclosure.

FIG. 3C shows a top view of the dual resonator structure of FIG. 2A, in accordance with some embodiments of the present disclosure.

FIG. 3D shows a bottom view of the dual resonator structure of FIG. 2A, in accordance with some embodiments of the present disclosure.

FIG. 3E shows a left side or right side view of the dual resonator structure of FIG. 2A, in accordance with some embodiments of the present disclosure.

FIG. 3F shows an elevation view of a co-wound solenoid of a dual resonator structure, in accordance with some embodiments of the present disclosure.

FIG. 3G shows a perspective view of a dual resonator structure including co-wound solenoid inner coils within an outer coil, in accordance with some embodiments of the present disclosure.

FIG. 4A shows an example radiofrequency circuit diagram associated with an inner coil of the dual resonator structure of FIG. 2A to tune a frequency of a ¹H channel, in accordance with some embodiments of the present disclosure.

FIG. 4B shows another example radiofrequency resonator circuit diagram associated with an inner coil of the dual resonator structure of FIG. 2A to tune frequency of a first (1H) channel, in accordance with some embodiments of the present disclosure.

FIG. 5A shows an example graph comparing a signal-to-noise ratio (SNR) of the dual resonator structure with a standard coil resonator at different frequencies, in accordance with some embodiments of the present disclosure.

FIG. 5B shows an example graph comparing a signal-to-noise ratio (SNR) of the dual resonator structure with a standard coil resonator, in accordance with some examples of the present disclosure.

FIG. 6 shows example NMR spectrum plots comparing the SNR of the dual resonator structure with the standard coil resonator at 600 MHz, in accordance with some embodiments of the present disclosure.

FIG. 7 shows example pulse width arrays comparing the homogeneity of magnetic fields of the dual resonator structure with the standard coil resonator, in accordance with some embodiments of the present disclosure.

FIG. 8 shows example plots comparing the homogeneity of magnetic field in the 1H channel with the homogeneity of magnetic field in X and Y channels of the dual resonator structure, in accordance with some embodiments of the present disclosure.

FIG. 9 shows an example of a plug-in module for tuning at least the first (1H) channel of the dual resonator structure, in accordance with some examples of the present disclosure.

FIG. 10 shows an example of a plug-in board into which the plug-in module is plugged for tuning at least the first (1H) channel of the dual resonator structure, in accordance with some examples of the present disclosure.

### DETAILED DESCRIPTION

The present disclosure is directed to NMR spectroscopy and particularly to a probe design used in an NMR spectrometer. More particularly, the present disclosure is directed to a dual resonator structure used in probes of NMR spectrometers. In certain embodiments, the present disclosure also provides for a plug-in module for a RF tuning circuit operating at radio and microwave frequencies of an NMR spectrometer resonator.

NMR spectroscopy is an analytical technique for determining the structure, dynamics, reaction state, and chemical environment of molecules. NMR spectroscopy is based on the concept of absorption of radiofrequency signals by nuclei enveloped in a magnetic field. When certain nuclei (such as 1H protons) are placed in a magnetic field, these nuclei resonate at a specific frequency. Proton (1H) detection methodologies in solid-state NMR (SSNMR) have been the focus of major efforts within the field for the benefits they provide to resolution and sensitivity of 1H detection. These benefits have allowed for increasingly complex experiments to determine the structure and dynamics of biological and material compounds. Recent methodological improvements in sample preparation, pulse sequence design, and commercially available probes with higher spinning rates have evolved 1H detection capabilities, facilitating higher resolution studies into the finer details of complex systems.

Despite these advances, relatively few improvements have been made to the probe radiofrequency (RF) circuit configured to tune a frequency to optimize 1H detection capabilities. Commercial SSNMR probes use a standard single coil design (referred to herein as a standard coil resonator) for ¹H detection. The standard single coil design does not allow for optimization of the RF circuit to take full advantage of the sensitivity obtainable from ¹H detection. In particular, the standard single coil design is configured to be tuned to function for multiple frequencies, including frequencies for observing ¹H (referred to as ¹H channel) as well as frequencies for observing nuclei other than ¹H (e.g., ¹³C, ¹⁵N, ³¹P, ²H, ²⁹Si, etc., collectively referred to herein as X and Y channels). Because ¹H nuclei have a different resonant frequency than non-¹H nuclei, a coil and circuit design that may be optimal for ¹H nuclei may not be optimal for another non-¹H nuclei. Thus, a single RF circuit provided by the standard single coil design is not optimal or most efficient at any of the desired frequencies. This leads to compromises in the probe quality factor, homogeneity, and efficiency of the ¹H channel.

The systems disclosed herein address the problems associated with the standard single coil design. In particular, the present disclosure provides a dual resonator structure in the RF circuit. The dual resonator structure allows for separation of a first (the ¹H) channel from the X and Y channels. This separation allows the frequency of the ¹H channel to be optimized independent from and simultaneously with the frequency of the X and Y channels, thereby improving the sensitivity and efficiency of the ¹H channel while maintaining the required performance on X and Y channels. The dual resonator structure includes an inner coil for optimizing performance of the ¹H channel and an outer coil for optimizing performance of the X and Y channels. The dual resonator structure is capable of tuning to higher frequencies (e.g., 600 megahertz to greater than 1 gigahertz (GHz), such as 1.1 GHz or higher) on the first (¹H) channel, while providing higher signal-to-noise ratio (SNR), increased sensitivity of detection, and greater homogeneity of magnetic fields. The dual resonator structure may be used in magic-angle spinning (MAS) probes or other types of probes used in NMR spectroscopy. For example, the dual resonator structure may be used with oriented sample methods or other SSNMR methods.

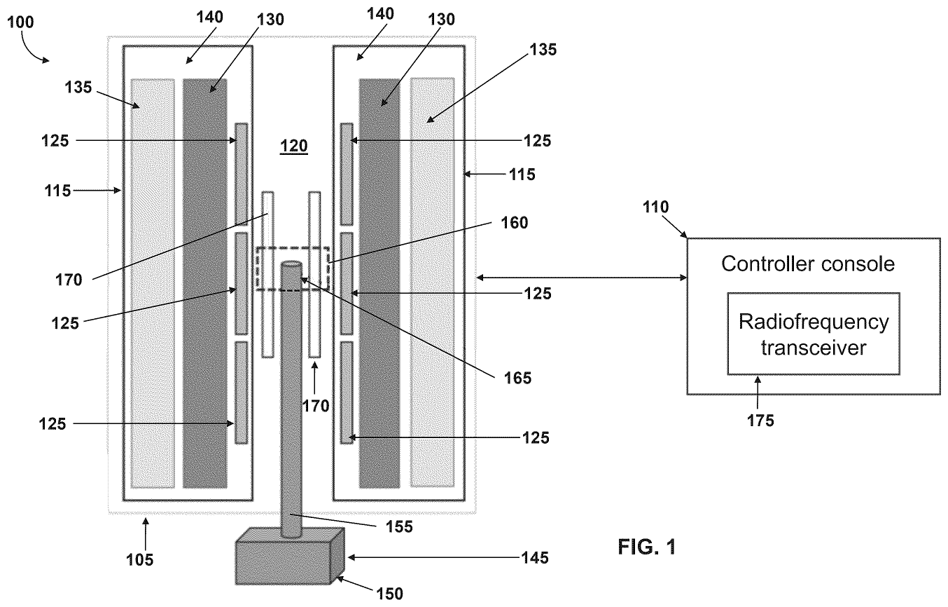

Referring to FIG. 1, a schematic example of an NMR spectrometer 100 is shown, in accordance with some embodiments of the present disclosure. The NMR spectrometer 100 may include a magnet shell 105 in communication with a controller console 110. The magnet shell 105 may be a cryogenic magnetic shell defining a superconducting housing 115 and a room-temperature bore 120 therein. In some embodiments, the magnet shell 105 and/or the superconducting housing 115 may be cylindrical or somewhat cylindrical in shape, although either of those components may assume other shapes, sizes, and/or configurations in other embodiments. In certain embodiments, superconducting housing 115 may include or be embodied as a cryogenic outer vacuum chamber. The superconducting housing 115 may be configured to house a high homogeneity superconducting magnet 125. In some embodiments, the superconducting magnet 125 may be made from coaxial coils of superconducting wire, although the superconducting magnet may assume other forms. Although six superconducting magnet sections are shown in FIG. 1 for the superconducting magnet 125, the number of sections, as well as shape and size of each section may vary from embodiment to embodiment. In some embodiments, a single superconducting magnet section may be used. In others, greater than or less than six superconducting magnet sections may be used depending on the strength of the magnetic field desired and the sample being analyzed. The superconducting magnet 125 may be desired to be kept at a specific temperature (e.g., at 4.2 Kelvin, the standard boiling point of liquid helium). Thus, in some embodiments, the superconducting magnet 125 may be surrounded by or immersed in a jacket of liquid helium 130 within the superconducting housing 115. Further, in some embodiments, the liquid helium 130 may be surrounded by a jacket of liquid nitrogen (e.g., kept at 77 Kelvin) 135 and/or vacuum 140 to minimize the rate of liquid helium evaporation.

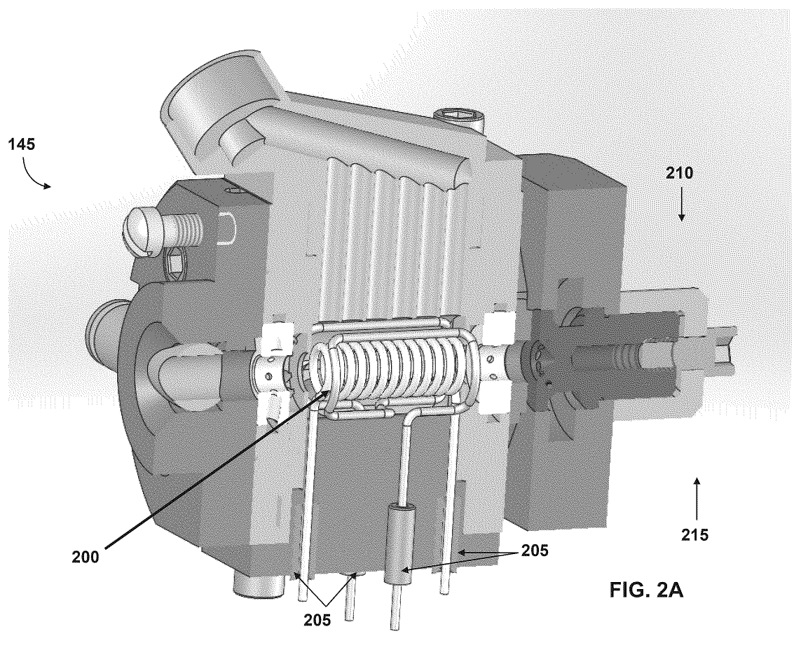

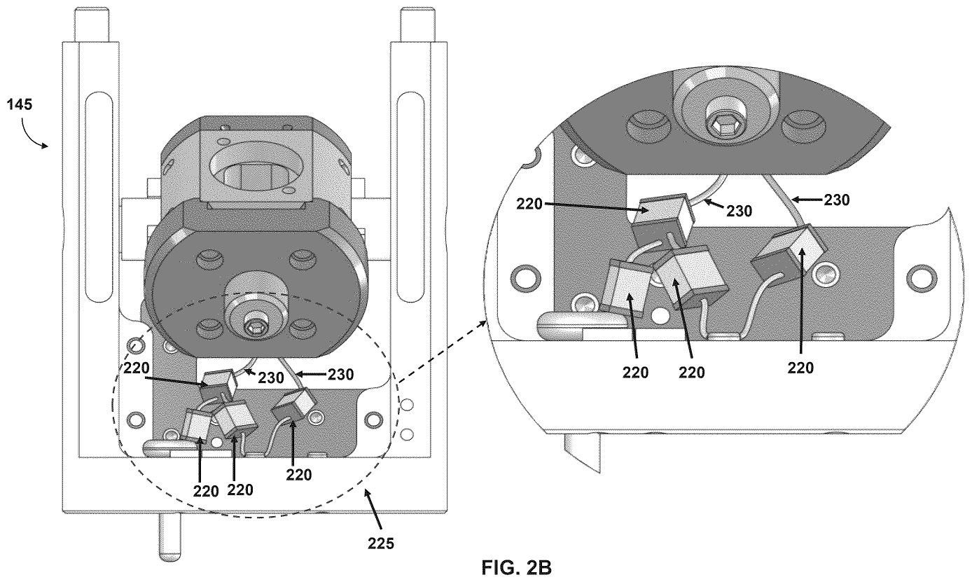

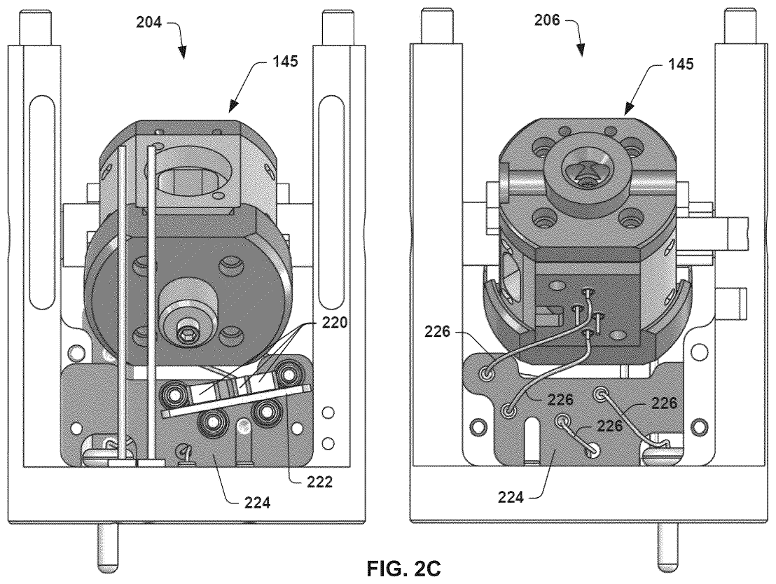

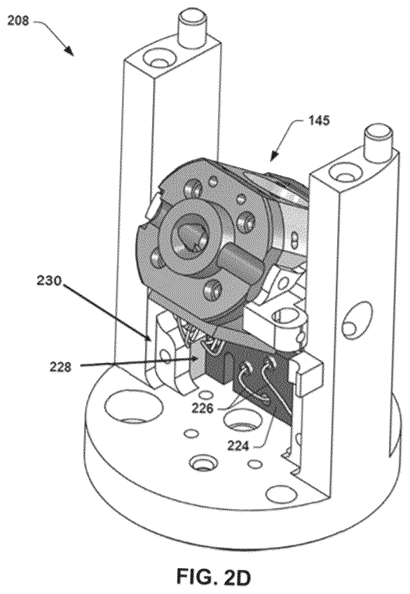

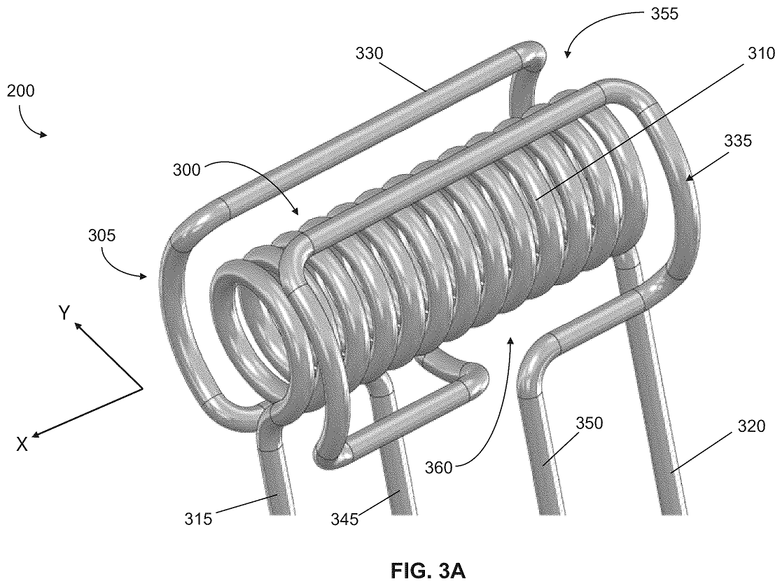

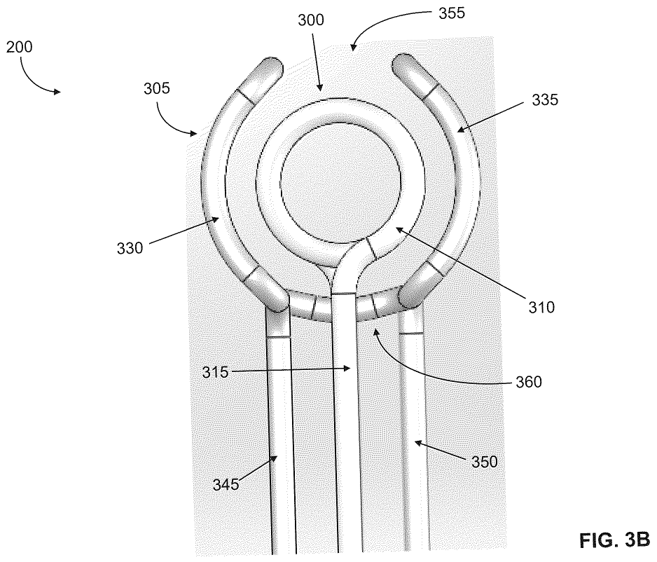

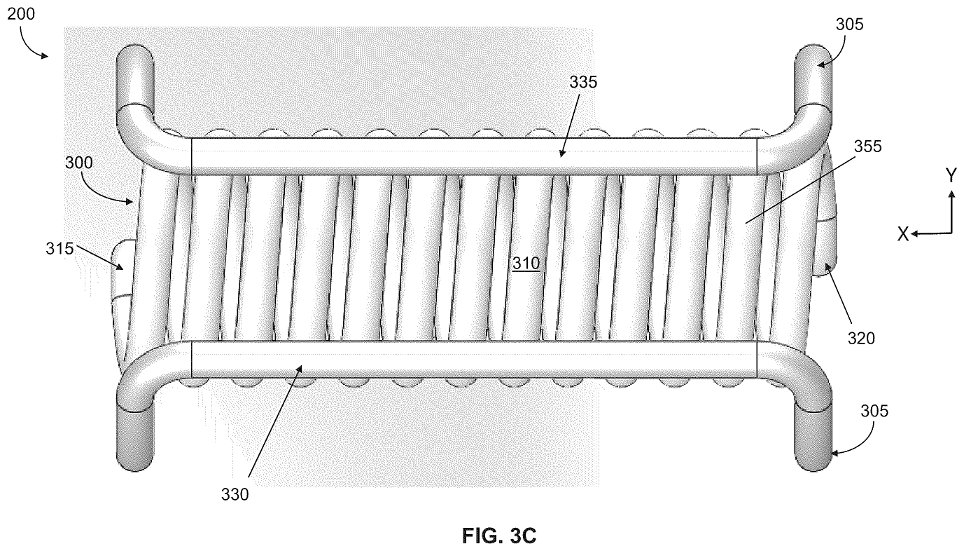

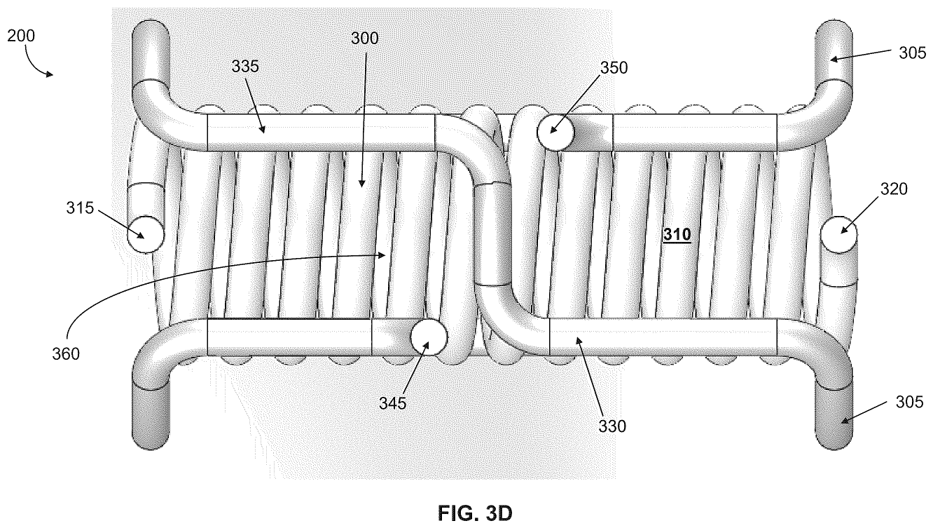

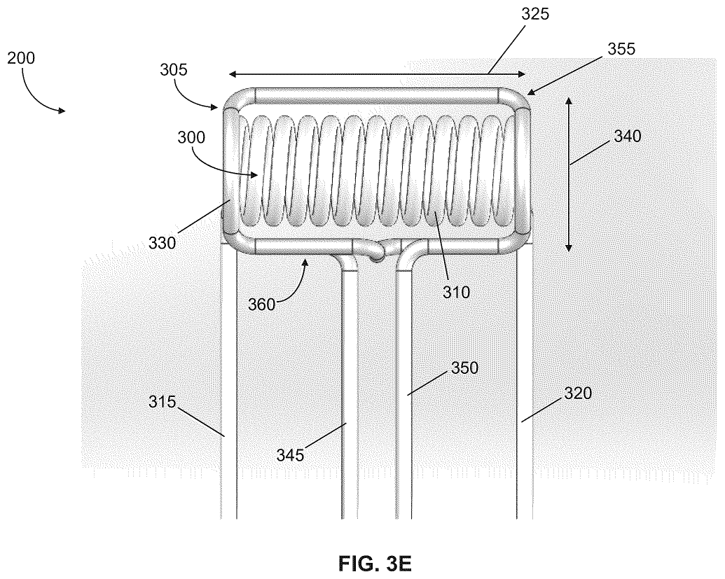

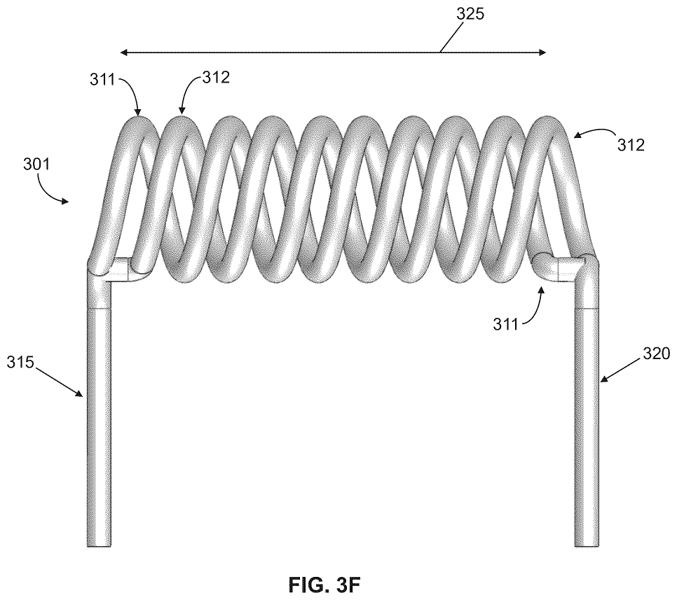

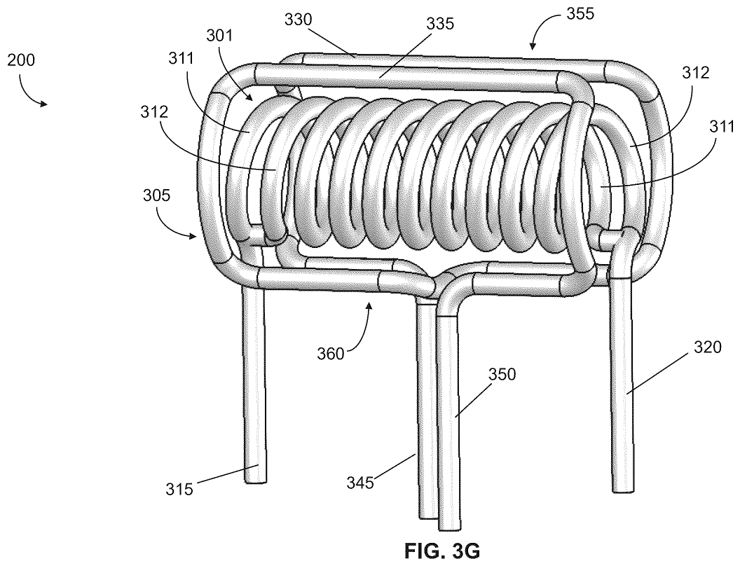

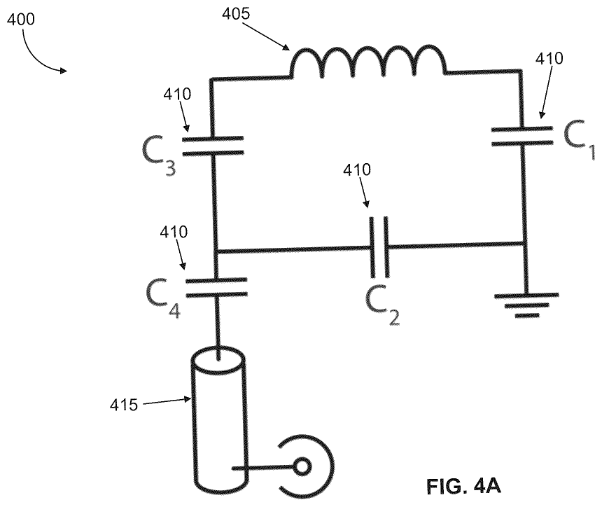

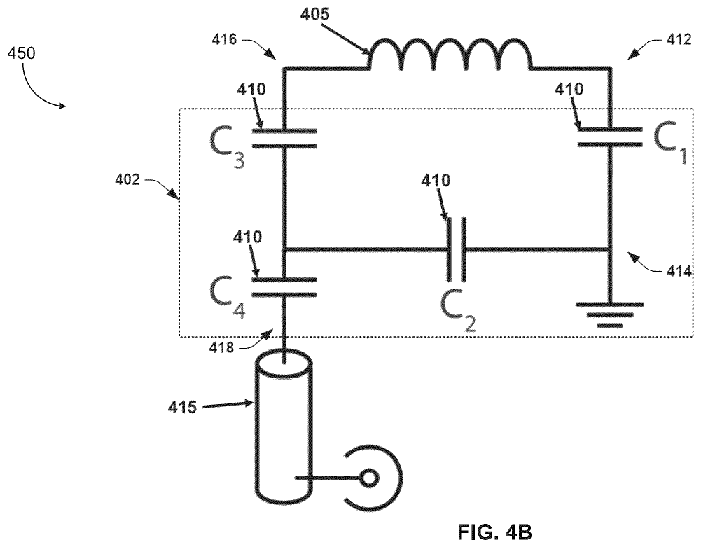

The bore 120 may be configured to house a probe 145. The probe 145 may include a probe base 150 and a probe body tube 155 extending from the probe base into the bore 120. An end portion 160 of the probe body tube 155 located at a distal end of the probe base 150 may define a probe head 165 in which a sample to be analyzed may be housed. The probe head 165 may be removable and may be independently modified (e.g., for fabrication, design, repair, etc.) before reattachment. The probe head 165 may include or be associated with a mechanism for spinning the sample (e.g., at the magic angle) and a mechanism for radio frequency excitation and detection. In particular, the probe head 165 may include a dual resonator structure (not shown in FIG. 1, exemplary embodiments of which is shown and described in FIGS. 2A-3G) within which the sample may be housed at the magic angle for spinning. The probe body tube 155 may house one or more tuning elements for adjusting the resonant frequencies, such as one or more electrical circuits, example embodiments of which are shown in FIGS. 4A and 4B. Example tuning elements may include transmission lines, inductors, fixed and/or variable capacitors, etc. The probe body tube 155 and/or the probe base 150 may include other components as well. The sample may be surrounded by a set of shimming coils 170 strategically positioned about the sample to adjust the homogeneity of the magnetic field over the sample. In some embodiments, the set of shimming coils 170 may include an assembly having a plurality of shim coil channels, for example 18-40 shim coil channels, embedded in a shim coil body. Although one set of shimming coils is shown, in other embodiments, additional sets of shimming coils may be provided.

To analyze the molecules of the sample placed in the probe head 165, the superconducting magnet 125 may be configured to generate a strong and stable magnetic field over the sample. The magnetic field causes the nuclei within the sample (e.g., ¹H, ¹³C, ¹⁵N, etc.) to align with or against the magnetic field. Further, in some embodiments, a radiofrequency (RF) pulse may be applied to the sample by a radiofrequency transceiver 175 via the controller console 110. In some embodiments, a frequency tuning operation may be used to allow the frequency of the RF pulse to match a resonance frequency of the nuclei being studied. In some embodiments, the frequency tuning may also be used to maximize the SNR for resulting in stronger NMR signals and more accurate spectra. In some embodiments, the frequency tuning operation may assist in stabilizing and maintaining the homogeneity of the magnetic coil via the set of shimming coils 170.

In some embodiments, the frequency tuning operation may be implemented using the one or more tuning elements in the probe 145 and the dual resonator structure (e.g., dual resonator structure 200) within which the sample is placed. In some embodiments, the dual resonator structure may be configured to tune to specific frequencies corresponding to the nuclei of interest. The dual resonator structure may be configured for operation at two or more different frequencies simultaneously. For example, the dual resonator structure may include a first coil, such as an inner coil, and may be configured to tune a first (¹H) channel of the inner coil to a first frequency and include a second coil, such as a saddle coil, and may be configured to tune X and Y channels to second and third frequencies. The frequency tuning may be needed to ensure that the RF field is at the correct frequency to excite the nuclei and detect their emitted signals. Thus, in some embodiments, the dual resonator structure may be configured for one or both of detection and transmission of the RF pulses. In various embodiments, the dual resonator structure may be configured for both transmission of RF pulses to the sample and detection of the RF pulses emitted from the sample. For example, and without limitation, in some embodiments, the dual resonator structure may be configured to generate an RF field based on the RF pulse to excite the nuclei in the sample, causing the nuclei to move from a lower energy state to a higher energy state (e.g., through the process of resonance). The dual resonator structure may also be configured to maintain a homogenous magnetic field around the sample and/or enhance the sensitivity of the probe 145. After the RF pulse is turned off, the excited nuclei may settle back to their lower energy states (e.g., through the process of spin-lattice relaxation).

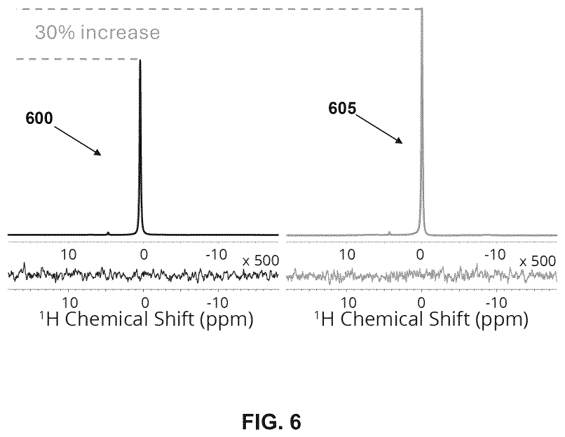

Upon the nuclei settling back to their lower energy state and application of an excitation pulse, the nuclei may emit RF signals, which may be detected by the dual resonator structure and transmitted to the RF transceiver 175. In some embodiments, the received and/or transmitted RF pulse may be amplified by an amplifier in electrical communication with the dual resonator structure, the RF transceiver 175, or both. The controller console 110 may include additional circuitry and componentry to analyze the received RF pulse. For example, in some embodiments, the controller console 110 may be configured to convert the received RF pulse from a time domain into a frequency domain using Fourier transform to obtain an NMR spectrum (an example of which is shown in FIG. 6, in part). The NMR spectrum may display peaks corresponding to different environments of the nuclei in the sample. The controller console 110 may facilitate analysis of the position, intensity, and other properties of these peaks to determine the structure of the molecules within the sample.

It is to be understood that only some components of the NMR spectrometer 100 are shown and described herein. In other embodiments, the NMR spectrometer 100, including each of the components described above, may include other or additional components that may be desired or considered useful to have in analyzing molecules of a sample.

Turning now to FIGS. 2A and 2B, example cutaway portions of the probe 145 are shown, in accordance with some embodiments of the present disclosure. The cutaway portions show an example dual resonator structure 200 mounted within the probe 145 (and particularly the probe head 165). The dual resonator structure 200 may be mounted at the magic angle or at other angles. The dual resonator structure 200 may be configured for spinning in some embodiments. The dual resonator structure 200 may be connected to one or more coil supports or feedthrough supports (e.g., copper coaxial feedthroughs-only some of which are shown) 205 and capacitors 220 (see FIG. 2B) configured to tune the frequencies of the ¹H channel and the X and Y channels.

As shown in FIG. 2A in conjunction with FIGS. 3A-3E, additional views of the dual resonator structure 200 are shown, in accordance with some embodiments of the present disclosure. Specifically, FIG. 3A shows an example perspective view of the dual resonator structure 200, FIG. 3B shows a front or back view (e.g., end views when viewed from the left side or right side of FIG. 2A) of the dual resonator structure, FIG. 3C shows a top view (e.g., when viewed in the direction indicated by arrow 210 of FIG. 2A) of the dual resonator structure, FIG. 3D shows a bottom view (e.g., when viewed in the direction indicated by arrow 215 of FIG. 2A) of the dual resonator structure, and FIG. 3E shows a left side or right side view (e.g., going into the page or coming out of the page) of the dual resonator structure, in accordance with some embodiments of the present disclosure. The front and back views of the dual resonator structure 200 may be symmetric (e.g., same), while the right side and left side views of the dual resonator structure may be symmetric (e.g., same).

Referring to FIGS. 2C and 2D, an embodiment of probe 145 having a plug-in module is shown. As shown in the example of FIG. 2C, a first view 204 of the probe 145 and a second view 206 of the probe 145 opposite the first view 204. The example of FIG. 2D demonstrates a plan view 208 of the probe 145.

The cutaway view 202 demonstrates that the dual resonator structure 200 may be mounted at the magic angle or at other angles. The dual resonator structure 200 may be configured to surround a spinning sample container in which a sample is confined. In some examples, a magic-angle spinning (MAS) rotor includes a cylindrical rotor configured to spin about a rotor axis. The dual resonator structure 200 may be connected to one or more coil supports or feedthrough supports 205 (as shown in FIG. 2A) and to capacitors 220 mounted on a plug-in module 222 configured to tune the frequencies of the first (¹H) channel and the X and Y channels. In the example shown in FIGS. 2C and 2D, the plug-in module 222 is mounted on a plug-in board 224 that may be affixed to the probe 145. In the examples shown in FIGS. 2C and 2D, the plug-in board 224 thus has a direct electrical (e.g., hard-wired) connection 232 to the dual resonator structure 200, to a transmission line associated with the RF transceiver 175, and to ground via wires 226. In this manner, the plug-in board 224 is hard-wired to the dual resonator structure. The example of FIG. 2D also demonstrates a relative location of the plug-in board 224 and a plug-in board for other electronics, such as the X and/or Y channel resonators, as well as a dielectric spacer 228 therebetween to mitigate cross-talk and/or noise between the respective plug-in boards.

As described herein, because the first (¹H) channel can be tuned to frequencies greater than 1 GHz (e.g., 1.1 GHZ), a RF circuit operating at microwave frequencies for tuning the first (¹H) channel can be implemented on a plug-in module, such as plug-in module 222. As described herein, the term “tuning circuit” refers to a set of capacitors that cooperate with an inductor to form at least a portion of the resonator of the NMR spectrometer (e.g., the first (¹H) channel of the dual resonator structure 200). In various embodiments, the plug-in module tuning circuit (hereinafter “plug-in module”) can be implemented as a prefabricated circuit board that includes high precision capacitors arranged in a specific geometric layout and with specific relative dimensions with respect to each other on a circuit board substrate. The circuit board substrate can be formed from a dielectric material that is selected based on specific dielectric and other specific material properties. Therefore, the plug-in module can mitigate the deleterious parasitic effects of the resonator circuit while operating at the very high tuning frequencies (e.g., greater than 1 GHz) of the ¹H channel.

In various embodiments, the plug-in module, such as plug-in module 222 shown in FIG. 2C, can be bench-tested as a unit subsequent to fabrication to exhibit known circuit characteristics for operation of the NMR spectrometer resonator. The plug-in module can thus be plugged in to a plug-in board (e.g., via press-fit) on the NMR probe to provide predictable and repeatable performance of the tuning circuit thereon. Because the plug-in module is implemented in a modular design, multiple plug-in modules with different respective circuit characteristics can be implemented for the NMR probe, such as based on conducting different NMR experiments at different frequencies and/or under operating conditions. Therefore, the plug-in module described herein can mitigate the deleterious parasitic effects of the resonator circuit while operating at the very high tuning frequencies (e.g., greater than 1 GHz) to which the ¹H channel is tuned. While the plug-in module is described herein as operating with respect to a dual resonator structure, the dual resonator structure is provided merely as an example, such that the plug-in module can operate to tune any frequency of a single resonator (e.g., the ¹H channel).

The modular plugging and unplugging of the plug-in modules to the NMR probe can result in significant time savings in switching between different NMR experiments while still allowing for predictable and repeatable performance of the tuning circuit. Therefore, additional time savings can be realized based on obviating testing of the tuning circuit between replacement of tuning circuits for different respective NMR experiments. Accordingly, the plug-in module described herein can provide significant benefits to the resonator of an NMR spectroscopy system.

As shown in FIGS. 2A-3E, the dual resonator structure 200 includes a dual coil structure. In particular, the dual resonator structure 200 includes an inner coil 300 and an outer coil 305. In some embodiments, the inner coil 300 may be a solenoid coil. In some embodiments, the outer coil 305 may be a saddle coil. In some embodiments, the inner coil 300 and/or the outer coil 305 may be other types of coils. In some embodiments, the inner coil 300 and the outer coil 305 may be spaced apart from one another. In other words, the inner coil 300 may not touch the outer coil 305 at any point. In various embodiments, inner coil 300 and outer coil 305 may be electrically isolated from one another. In various embodiments, outer coil 305 may be radially spaced from inner coil 300 and partially encompass inner coil 300 as will be described below. In some embodiments, the sample may be placed within the inner coil 300. In some embodiments, the inner coil 300 may be configured to tune the first (¹H) channel to a first frequency and the outer coil 305 may be configured to tune the X and Y channels to second and third frequencies, different from the first frequency. In some embodiments, the inner coil 300 and the outer coil 305 may be tuned independently and simultaneously. In some embodiments, the first frequency may be higher than the second and/or the third frequencies. The first channel may be tuned to a higher frequency than one or both of the X and Y channels. As an example, the first frequency to which the first (¹H) channel is tuned can be a high frequency (e.g., greater than 1 GHz). While the proton ¹H channel (e.g., the first channel) is described generally herein, other nuclei (e.g., fluorine 19F) can be implemented for an NMR experiment described herein, with the first frequency being tuned to accordingly. In some embodiments, the X and Y channels may be used to observe nuclei other than hydrogen (e.g., proton (¹H)) and fluorine (¹⁹F). For example, in some embodiments, the X and Y channels may be used to observe nuclei such as ¹³C, ³¹P, ²⁹Si, ²H, and ¹⁵N, among others. In some embodiments, the first (¹H) channel may be used to observe proton nuclei. By using different coils and/or different frequencies for different nuclei, optimal frequencies based on the type of nuclei may be used by each of the coils described herein.

In some embodiments, to tune the first (¹H) channel independently from the X and Y channels, the ends of each of the inner coil 300 and the outer coil 305 may be connected to one or more capacitors 220 (see FIG. 2B). An exploded view 225 shows the capacitors 220 in greater detail. The capacitors 220 may be connected to the one or more coil leads 230 below the feedthrough supports 205, which in turn may be connected to the dual resonator structure 200. The capacitors 220 may be connected together to form an electric circuit, details of which are discussed in FIG. 4A below. Although four capacitors 220 are shown in FIG. 2B, in other embodiments, the number of capacitors may vary to include less than or greater than four capacitors.

In some embodiments, the first (¹H) channel may be tuned to a frequency of 600 megahertz (MHz). In some embodiments, the first (¹H) channel may be tuned to a frequency of 750 MHz. In some embodiments, the first (¹H) channel may be tuned to a frequency of 900 MHz. In some embodiments, the first (¹H) channel may be tuned to a frequency range of 595 MHz to 1.1 Gigahertz (GHz). For example, in some embodiments, the first (¹H) channel may be tuned to a frequency of 800 MHz, 900 MHz, 1000 MHz, 1100 MHz, etc. In some embodiments, a frequency range of greater than 595 MHz may be desired for the first (¹H) channel. In some embodiments, a frequency range of below 595 MHz may be used as well. An example of tuning the frequency of the inner coil 300 is discussed below with respect to FIG. 4A. Further, in some embodiments, the X and Y channels may be tuned over a range up to ~40.48% of the first (¹H) channel frequency, corresponding to 31P, to as low as 10% of the first (¹H) channel frequency, corresponding to the 15N resonance. For example, for a 600 MHz first (¹H) channel frequency, the X and Y channels may be tuned to a frequency of 60 MHz to 245 MHz, etc.

In some embodiments, the inner coil 300 and the outer coil 305 may each be made using a susceptibility matched wire. The susceptibility matched wire may be configured to minimize magnetic susceptibility differences between the wire of the coil and the surroundings. By minimizing magnetic susceptibility differences, unnecessary distortions in the magnetic field may be avoided. In various embodiments, the inner coil 300 and the outer coil 305 may be formed by a common material (i.e., the same material). In various other embodiments, inner coil 300 may be made from a first material and outer coil 305 may be made from a second material, the second material distinct from the first material. In certain other embodiments, one or both of inner coil 300 and outer coil 305 may be made from a combination of materials. For example, and without limitation, inner coil 300 may be formed from a first material and a second material (e.g., braiding, laminating, twisting, etc.) and the outer coil 305 may be formed from a third material and a fourth material. In another example, and without limitation, inner coil 300 may be formed from a first and a second material and outer coil 305 may be formed from the same first material and the second material. That is to say, in some embodiments, inner coil 300 and outer coil 305 may be each formed from a combination of materials, whether common between the two coils, or distinct. Examples of materials that may be used for susceptibility matched wire may include metals, alloys and composites such as glass-filled epoxy composite, polyetherimide, borosilicate glass, zirconium dioxide, polychlorotrifluoroethylene, copper with palladium coating, copper, aluminum, silver and gold, etc. In various embodiments, each coil may be formed from a combination of materials. In some embodiments, one or more coils may be formed from a first core material, an extruded material disposed on the core material, and plating disposed on the extruded material. For example, and without limitation, one or more of the herein described coils may be formed from an aluminum core, a copper extrusion disposed over the aluminum core and plated with gold—wherein each of these layers is configured to define certain electrical and/or mechanical characteristics of the wire. As an example, the copper extrusion may define the resistivity of the wire, and the aluminum and gold may be configured to ensure zero magnetic susceptibility. This disclosure does not seek to limit the material choices of wires used to form one or more of the herein described coils and one of skill in the art would appreciate that material selection, combination of selected materials, and relative dimensions and/or purities/alloys of said materials may be predetermined to optimize one or more electrical or mechanical characteristics of one or more coils as described herein. In some embodiments, other suitable wire materials may be used for inner coil 300 and/or the outer coil 305 alone or in combination.

Further, in some embodiments, the wire (whether susceptibility matched or not) of the inner coil 300 and the outer coil 305 may be of uniform thickness. In some embodiments, the thickness of the wire used for the inner coil 300 may be the same as the thickness of the wire used for the outer coil 305. In other embodiments, the inner coil 300 and the outer coil 305 may be of different thicknesses. In some embodiments, the wire used for the inner coil 300 and/or the outer coil 305 may be a 22-gauge wire or a 24-gauge wire. In some embodiments, a 22-30-gauge wire may be used for the inner coil 300 and/or the outer coil 305. In other words, in some embodiments, a thickness of half a millimeter or less may be used for the inner coil 300 and/or the outer coil 305 depending on the current capacity desired for the wire. Further, in some embodiments, the entire structure of the inner coil 300 may be composed of a single wire. Similarly, in some embodiments, the entire structure of the outer coil 305 may be composed of a single wire. In some examples, the inner coil is formed from a first material and the outer coil is formed from a second material. In other embodiments, the multiple pieces of wire joined together may be used for either the inner coil 300 or the outer coil 305. In some embodiments, when inner coil 300 and outer coil 305 are formed by a plurality of wire segments joined together, said joints or points along respective wires where they are joined may be selected to minimize adverse electrical or magnetic effects, such as proximate the ends or spaced from the sample positioned within inner coil 300. In various embodiments, the material and thickness of wire, in concert with or independent of the geometrical shape of inner coil and outer coil 305, may be configured to exhibit suitable rigidity or stiffness. For example, inner coil 300 and outer coil 305 may be configured to be freestanding wires suspended within a cavity within probe head 165 and at least partially encapsulating a sample therebetween. Inner coil 300 and outer coil 305 may be configured to withstand turbulent environments, such as vibrations imparted through one or more spinning, rotating or otherwise moving components, and one or more gas flows, such as air or other gases passing over and through the inner coil 300 and/or outer coil 305.

Referring now to FIG. 3A, a perspective view of an exemplary embodiment of the dual resonator structure 200 is shown alone, for clarity. With respect to the inner coil 300, as mentioned above, in some embodiments, the inner coil may be a solenoid coil. Thus, in some embodiments, the inner coil 300 may have a helical coil structure 310 wound about an X-axis and spanning between two opposing ends, first end 315 and second end 320. Each of the first end 315 and second end 320 may be lengths of substantially straight or linear wire continuous with the first turn and last turn, respectively. In certain other embodiments, first end 315 may be a straight length of wire coupled to the arcuate first turn of helical coil structure. In certain other embodiments, second end 320 may be coupled to the arcuate last turn of helical coil structure 310. The helical coil structure 310 may therefore form a plurality of windings, each winding having a substantially circular cross section (when viewed orthogonally from first end 315 and second end 320, such as in FIG. 3B). The span of helical coil structure 310 between first end 315 and second end 320 may define a length 325 (as shown clearly in FIG. 3E). Each of the two opposing ends, first end 315 and second end 320 may be connected to one or more feedthrough supports 205 to tune the frequency of the first (¹H) channel (e.g., via the capacitors 220 connected to the feedthrough supports shown in FIG. 2A). In some embodiments, inner coil 300 may have the capacitors 220 in close proximity thereto to minimize losses due to voltage standing waves and to keep the voltage in balance across the solenoid coil. The number of turns in the solenoid coil and the spacing between two adjacent turns may vary from embodiment to embodiment. In certain embodiments, inner coil 300 and specifically the helical coil structure 310 may include 13 turns between first end 315 and second end 320. In various embodiments, helical coil structure 310 may have a single pitch over the length 325. In other embodiments, helical coil structure 310 may have a variable pitch over its length 325. That is to say, the spacing of adjacent turns of the helical coil structure 310 may vary at points along length 325. For example, and without limitation, the spacing between adjacent turns (i.e., the pitch) may be greater proximate the first end 315 and the second end 320. In another example, the pitch of helical coil structure 310 may be greater proximate a central portion relative to the portions proximate the first end 315 and the second end 320. In certain other embodiments, the pitch of helical coil structure 310 may be greater proximate first end 315 relative to proximate second end 320. In certain other embodiments, the pitch of helical coil structure 310 may alternate over subsequent portions along length 325. In some embodiments, reducing the number of turns in the helical coil structure 310 may increase the frequency of the first (¹H) channel. Likewise, in some embodiments, increasing the spacing between adjacent turns of the helical coil structure 310 may increase the frequency of the first (¹H) channel. In some embodiments, a larger spacing between adjacent turns may not be desired since the larger spacing may create ripples in the magnetic field, thereby adversely impacting the performance and efficiency of the sample analysis.

In some embodiments, two co-wound solenoid coils may be used to reduce the spacing between adjacent turns. An illustrative embodiment of co-wound inner coil 301 can be seen in at least FIG. 3F and further the co-wound inner coil 301 within dual resonator structure 200 in FIG. 3G. For example, and without limitation, two co-wound solenoid coils 311, 312 may be interleaved such that respective turns of each solenoid turn around one another in a double helix, forming inner coil 301. In said embodiments, such as inner coil 301 including two co-wound solenoid coils 311, 312, the pitch of each solenoid may be selected to account for the solenoid coils 311, 312 of the other such that the co-wound arrangement is disposed at a predetermined pitch over the length 325. In such embodiments including co-wound solenoid coils 311, 312, each solenoid may include a first end and a second end electrically coupled to one or more tuning circuits as described herein. In further embodiments, the co-wound solenoid coils 311, 312 may be electrically and/or mechanically coupled together as can be seen in FIGS. 3F-3G. In the embodiment shown in FIG. 3F, the first solenoid coil 311 and a second solenoid coil 312 may be coupled to one another at a point proximate first end 315 and coupled at a second point proximate second end 320, for example, to a common tuning circuit. In various embodiments, each solenoid coil 311, 312 may be sized identically, having the same diameter pitch, number of turns and other like geometrical characteristics. In other embodiments, each solenoid coil 311 and 312 may each have distinct geometrical and dimensional characteristics sized and design to co-wind to form inner coil 301. In various other embodiments, inner coil 301 may be formed by more than two co-wound solenoid coils 311, 312, such as three, four, five, six, seven, eight, nine, ten or more solenoids interleaved with one another to achieve the predetermined pitch, length or electromagnetic capabilities. In some embodiments, a total length 325 of the solenoid coil may be dependent upon the geometry of the probe head 165, the size of the sample, and/or the angle at which the solenoid coil is to be mounted. In various embodiments, the solenoid coil may be mounted at or near the magic angle, as described herein. That is to say, inner coil 300 may be sized to fit within probe head 165, and can be adjusted in length 325, number of turns and pitch (spacing of turns).

With respect to the outer coil 305, as mentioned above, in some embodiments, the outer coil 305 may be a saddle coil, an exemplary embodiment of which is shown in FIGS. 2A-2B within the probe head and 3A-3E with inner coil 300 or 301 in FIG. 3G, respectively. The outer coil 305, embodied herein as a saddle coil, may be formed from a continuous length of wire bent or otherwise shaped to form two opposite and opposing inwardly curved portions. In various embodiments, the outer coil 305 may include a first saddle portion 330 and a second saddle portion 335. In certain embodiments, a first saddle portion 330 may be positioned on a first lateral side of helical coil structure 310 of the solenoid coil. Accordingly, the outer coil 305 may be configured such that the second saddle portion 335 is opposingly positioned on a second lateral side of helical coil structure 310 of the solenoid coil. That is to say, the first saddle portion 330 and the second saddle portion 335 may be shaped to at least partially surround the inner coil 300 over length 325. The first saddle portion 330 and the second saddle portion 335 may each extend along the length 325 of the helical coil structure 310 and may have a loop-like shape. For example, in some embodiments, each of the first saddle portion 330 and the second saddle portion 335 may form an open substantially rectangular or rectilinear loop structure, although in other embodiments, one or both saddle portions may assume other shapes and sizes. In some embodiments, both the first saddle portion 330 and the second saddle portion 335 may have the same shape and size. In some embodiments, the first saddle portion 330 and the second saddle portion 335 may be curved towards each other (e.g., see FIGS. 3A, 3B). As shown in the end-on view of FIG. 3B, first saddle portion 330 may subtend an angle inwardly from the X-axis (running centrally within inner coil 300). Further, second saddle portion 335 may subtend an equal but opposite angle inwardly. First saddle portion 330 and second saddle portion 335 may be substantially concentric with the inner coil 300 along the loop-like structures. In various embodiments, outer coil 305 may be positioned as close as possible with inner coil 300 but radially spaced therefrom to prevent arcing between inner coil 300 and outer coil 305. In certain embodiments, the first saddle portion 330 and the second saddle portion 335 may be radially spaced from the helical coil structure 310 by approximately 0.4 millimeters (mm), however greater or lesser spacing may be utilized based on coil material and operating parameters. In some embodiments, a height 340 of each of the first saddle portion 330 and the second saddle portion 335 (i.e., the distance along a chord formed between the upper and lower termini of respective saddle portions) may be greater than the diameter of the helical coil structure 310 (e.g., see FIG. 3E). That is to say, the first saddle portion 330 may be concentric with but have a greater diameter than helical coil structure 310. For example, the first saddle portion 330 extends about a first arcuate path approximately concentric with the first side 355 of the inner coil 300. Similarly, second saddle portion 335 may be concentric with but have a greater diameter than helical coil structure 310, the second saddle portion 335 oppositely curved than the first saddle portion 330.

Further, in some embodiments, the curvature of the first saddle portion 330 and the second saddle portion 335 may extend slightly over and under the helical coil structure. That is to say, in various embodiments, the arc of each saddle portion may extend around the helical coil structure 310 in a transverse plane (as seen in FIG. 3B) may be greater than 90°. In certain other embodiments, the first saddle portion 330 and the second saddle portion 335 may be lesser than 90°. As previously described above, the first and second saddle portions 330, 335 may subtend any angle about helical coil structure 310, such as from 45° to about 180°. Each of the first saddle portion 330 and the second saddle portion 335 may include one end of the saddle coil. That is to say, in embodiments, where outer coil 305 (formed by first saddle portion 330 and second saddle portion 335) are formed from a single wire or a plurality of lengths of wire joined end to end and shaped, the outer coil 305 may include first outer coil end 345 extending from the first saddle portion 330 and a second outer coil end 350 extending from the second saddle portion 335. For example, the first saddle portion 330 may include a first outer coil end 345 and the second saddle portion 335 may include a second outer coil end 350. The first outer coil end 345 and the second outer coil end 350 may each be connected to the capacitors 220 (e.g., via the coil leads 230 below the feedthrough supports 205) for tuning the frequency of the X and Y channels independent from that of the first (¹H) channel. In some embodiments, the X and Y channel frequency tuning may be performed by the tuning elements other than capacitors. In some embodiments, these tuning elements (other than capacitors) may be able to provide a higher voltage threshold for operation than capacitors in some frequency ranges.

Referring still to the outer coil 305, in some embodiments, the first outer coil end 345 may be on one side of the inner coil 300 and the second outer coil end 350 may be on the opposite side of the inner coil between the first end 315 and second end 320 of the inner coil 300. In some embodiments, each outer coil end 345, 350 of the outer coil 305 may be closer to one end of the inner coil 300. For example, in some embodiments, the first outer coil end 345 may be closer to the first end 315 of the inner coil 300 and the second outer coil end 350 may be closer to the second end 320 of the inner coil 300. The relative arrangement of first outer coil end 345 proximate first end 315 and second outer coil end 350 proximate second end 320 may be configured for voltage distribution and circuit balancing. Additionally, the first saddle portion 330 and the second saddle portion 335 may be configured to be open and parallel along the length 325 on a first side 355 (e.g., top or upper side) of the helical coil structure 310, with the wire of outer coil 305 crossing over between the left and right lateral sides of the helical coil structure on a second side 360 (e.g., bottom) of the helical coil structure. That is to say, the upper portions of respective saddle portions that run along the length 325 may be spaced from one another proximate the first side 355, as shown in FIGS. 3A-3C. Thus, in various embodiments, the inner coil 300 and the outer coil 305 may provide for a crossed coil design having a crossed portion on a third side of the inner coil 300. Therefore, the first saddle portion 330 and the second saddle portion 335 have a crossed portion on a third side of the inner coil 300. By using the crossed coil design, the outer coil 305 may be made from a single wire. The crossed coil design may also be used to improve the performance of the outer coil 305 by independently optimizing its tuning circuit.

Further, in some embodiments, the magnetic fields of the inner coil 300 and the outer coil 305 may be orthogonal to one another. In some embodiments, the RF magnetic field (e.g., B₁ field) of the inner coil 300 may be along axis of the magic angle (e.g., X-axis) and the RF magnetic field (e.g., B₁ field) of the outer coil 305 may be orthogonal to the axis of the magic angle (e.g., Y-axis). In some embodiments, the magnetic field generated by the superconducting magnet 125 (e.g., B₀ field) may be along a Z-axis (along longitudinal axis of bore 120 shown in FIG. 1). In various embodiments, dual resonator structure 200 may also provide a high homogeneity for the magnetic fields generated by both the inner coil 300 and the outer coil 305 to provide an effective overlap of the magnetic fields and enable high performance for many types of NMR pulse sequences. The radial spacing and substantially orthogonal orientation of the inner and outer resonators reduce mutual inductance between resonators, enabling independent impedance matching and frequency optimization. Electrical isolation between the inner and outer resonators is achieved by radial spacing between the solenoid coil and saddle coil, independent feedthrough supports, and separate tuning circuits.

Turning now to FIG. 4A, an example electric circuit 400 is shown, in accordance with some embodiments of the present disclosure. The electric circuit 400 is an RF circuit configured to tune the frequency of the first (¹H) channel via the inner coil 300. In particular, the configuration of the electric circuit 400 that is shown is configured to tune the frequency of the first (¹H) channel to 750 MHz. The electric circuit 400 is a resonant circuit (e.g., an LC circuit) having an inductor 405 and one or more capacitors 410 (C1-C4). The capacitors 410 are the capacitors 220 that are connected to the coil leads 230 below the feedthrough supports 205 mentioned above. The number of capacitors in the electric circuit 400 may vary based on the frequency that is desired to be tuned for the first (¹H) channel. For example, in some embodiments, to tune the frequency of the first (¹H) channel to 600 MHz, only two of the four capacitors (e.g., C1 and C2) may be used. In other embodiments, to tune the frequency of the first (¹H) channel to 600 MHz, additional performance benefit may be achieved by using more than two capacitors (e.g., using all of the C1-C4 capacitors). In some embodiments, to tune the frequency of the first (¹H) channel to 750 MHz, all four of the four capacitors (e.g., C1-C4) may be used. In other embodiments, depending on the frequency being tuned, greater than or less than four capacitors may be needed. The inductor 405 in the electric circuit 400 may be configured to store energy in a magnetic field when current flows through the inductor, and each of the capacitors 410 may be configured to store energy in an electric field between its plates when a voltage is applied across the capacitor(s).

The electric circuit 400 may have a natural or resonant frequency at which the electric circuit oscillates. In some embodiments, the resonant frequency may be determined by the values of inductance of the inductor 405 and the capacitance of the capacitors 410. In some embodiments, the resonant frequency may be defined by:

$$Frequency = \frac{1}{\sqrt{L C}}$$

In the Equation above, Frequency is the resonant frequency of the electric circuit 400, L is the inductance value of the inductor 405 and C is the capacitance value of each of the capacitors 410. By adjusting the value(s) of the capacitors 410, the Frequency may be adjusted. At resonance, the energy in the electric circuit 400 oscillates between the inductor 405 and the capacitors 410, creating a sinusoidal waveform.

In the electric circuit 400, capacitor C2 is connected in parallel to the inductor 405 and between the capacitors C1 and C3 on one end and ground (e.g., 0 Volts) on the other end. Capacitor C1 is connected to the inductor 405 at one end and to ground on the other end. Capacitor C3 is connected to the inductor 405 at one end and to the capacitors C4 and C2 at the other end. The capacitor C4 is connected to the capacitors C3 and C2 at one end and to a tune tube assembly 415 at the other end. The capacitors C1 and C3 may be used to balance the circuit by placing the voltage minimum near the center of the inner coil 300, leading to an increased homogeneity (of magnetic field) and circuit efficiency. Thus, the voltage is minimized by balancing the circuit, which yields a maximum in the magnetic field. Capacitor C2 may function as a shunt to ground to lower the resonant frequency. Capacitor C4 may be used to decrease the voltage standing wave ratio along the transmission line, resulting in a greater efficiency of power delivery to the resonant circuit. By using various combinations of C1-C4 and different capacitance values of C1-C4, the inner coil 300 may be optimized to be both balanced and efficient at a desired frequency (e.g., 750 MHz). In some embodiments, the optimal tuning of the frequency of the first (¹H) channel may also optimize the sensitivity and efficiency of detection of ¹H nuclei.

Referring now to FIG. 4B, another exemplary radiofrequency resonator circuit diagram associated with an inner coil of the dual resonator structure of FIG. 2A to tune frequency of a first (¹H) channel, in accordance with some embodiments of the present disclosure, such as the probes shown in FIGS. 2C and 2D, is shown.

The electric resonator circuit 450 is an RF circuit that can be configured to tune the frequency of the first (¹H) channel via the inner coil 300. In particular, the configuration of the electric resonator circuit 450 that is shown is configured to tune the frequency of the first (¹H) channel to approximately 1.1 GHz. The electric resonator circuit 450 is a resonant circuit (e.g., an LC circuit) having an inductor 405 and one or more capacitors 410 (C1-C4). The capacitors 410 can correspond to the capacitors 220 mounted on the plug-in module 222 and electrically connected to the coil leads 230 below the feedthrough supports 205 described above and shown in FIGS. 2C-2D. Therefore, the electric resonator circuit 450 includes a tuning circuit 402 that can correspond to portion of the electric resonator circuit 450 associated with the plug-in module 222. Common portions between electric resonator circuit 450 may operate similarly to those components as shown in FIG. 4A as the electrical circuit 400.

In the electric resonator circuit 450, capacitor C2 is connected in parallel to the inductor 405 and between the capacitors C1 and C3 on one end and ground (e.g., 0 volts) on the other end. Capacitor C1 is connected to the inductor 405 at a node 412 and to a ground node 414 on the other end. Capacitor C3 is connected to the inductor 405 at a node 416 and to the capacitors C4 and C2 at the other end. The capacitor C4 is connected to the capacitors C3 and C2 at one end and to a tune tube assembly 415 at 418. The tube assembly 415 includes a transmission line. The capacitors C1 and C3 may be used to balance the circuit by placing the voltage minimum near the center of the inner coil 300, leading to an increased homogeneity of magnetic field and circuit efficiency. Capacitor C2 may function as a shunt to ground to lower the resonant frequency. Capacitor C4 may be used to decrease the voltage standing wave ratio along the transmission line, resulting in a greater efficiency of power delivery to the resonant circuit. By using various combinations of C1-C4 and different capacitance values of C1-C4, the inner coil 300 may be optimized to be both balanced and efficient at a desired frequency (e.g., 1.1 GHZ). In some examples, the optimal tuning of the frequency of the ¹H channel may also optimize the sensitivity and efficiency of detection of ¹H nuclei.

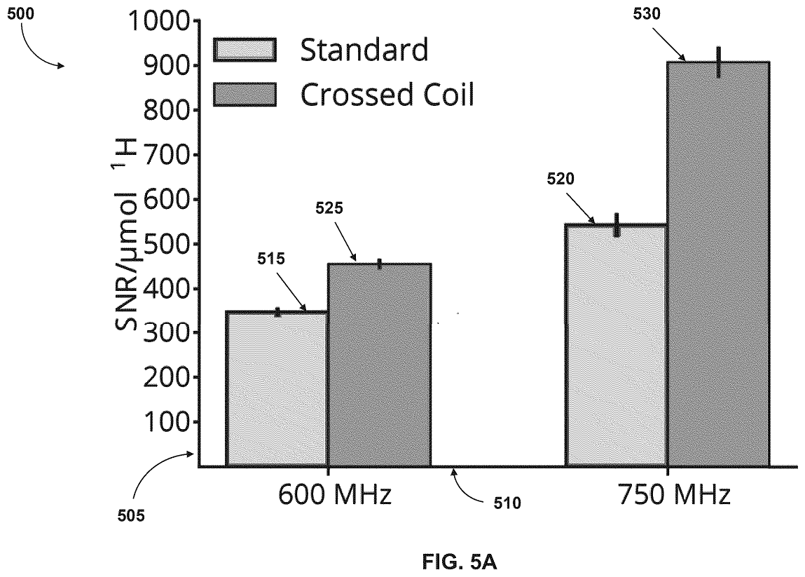

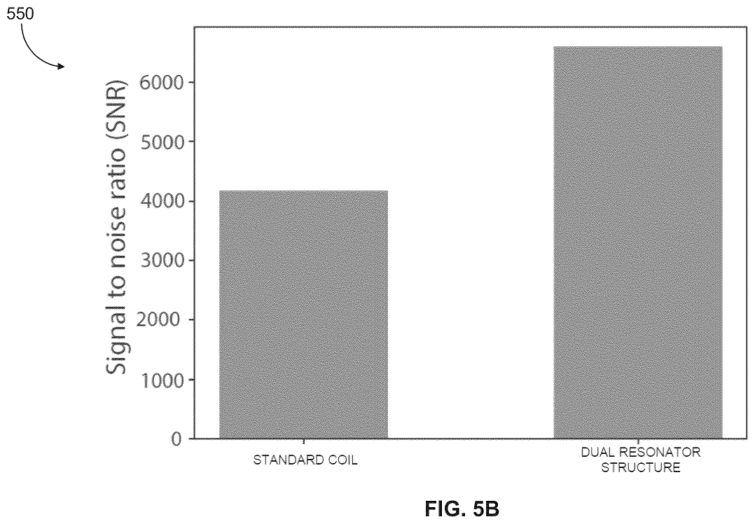

Turning to FIG. 5A, an example graph 500 comparing the SNR at different frequencies of first (¹H) channel between a standard coil resonator and the dual resonator structure 200 is shown. The standard coil resonator includes a single coil design. The graph 500 plots SNR/micromole of the first (¹H) channel on Y-axis 505 against frequency on X-axis 510. The graph 500 demonstrates the relative improvements between standard coil resonator and dual resonator structure 200 at 25 kHz spinning, normalized per micromole of sample tetrakis (trimethylsilyl) silane (TKS) used in the probe. A higher SNR/micromole provides greater signal. The graph 500 includes a first set of bars 515 and 520 corresponding to the standard coil resonator and a second set of bars 525 and 530 corresponding to the dual resonator structure 200. The bars 515 and 525 correspond to the frequency of 600 MHz while the bars 520 and 530 correspond to the frequency of 750 MHz. Comparing the bars 515 and 525, at 600 MHz, the dual resonator structure 200 has a higher SNR/micromole than the standard coil resonator. Comparing the bars 520 and 530, at 750 MHz, the dual resonator structure 200 has a higher SNR/micromole than the standard coil resonator.

Further, comparing the bars 525 and 530, the dual resonator structure 200 has a higher SNR/micromole at 750 MHz than at 600 MHz. Thus, the graph 500 demonstrates that the dual resonator structure 200 provides a 30% improvement at 600 MHz but an even greater improvement of 66% at 750 MHz compared to the standard coil resonator. As the magnetic field increases and the ¹H frequency increases, the ¹H circuit can be separately optimized. The graph 500 demonstrates that as the tuning frequency increases, the SNR increases as well. These improvements are a direct result of separating the first (¹H) channel frequency tuning circuit from the X and Y channels frequency tuning circuits through the use of the dual resonator structure 200.

Turning to FIG. 5B, an example graph 550 comparing the SNR of the ¹H channel between a standard coil resonator and the dual resonator structure 200 at approximately 1.1 GHz is shown, in accordance with some examples of the present disclosure. The standard coil resonator includes a single coil design. The graph 550 demonstrates the relative improvements between a standard single coil resonator and the dual resonator structure 200, such as used in an NMR probe. The graph 550 thus demonstrates that the dual resonator structure 200 has a higher SNR (e.g., SNR of approximately 6600) than the standard coil resonator (e.g., SNR of approximately 4200). Such an improvement is a direct result of separating the ¹H channel frequency tuning circuit from the X and Y channels frequency tuning circuits through the use of the dual resonator structure 200.

Turning to FIG. 6, example NMR spectrum plots 600 and 605 are shown, in accordance with some embodiments of the present disclosure. The NMR spectrum plots 600 and 605 correspond to ¹H measurements detected from a TKS sample using the standard coil resonator and the dual resonator structure 200, respectively. The NMR spectrum plots 600 and 605 were obtained using one radiofrequency pulse on the same sample at the same spinning rate, using the optimal ¹H 90° pulse to compare the standard coil resonator and the dual resonator structure 200. The dual resonator structure 200 and the standard coil resonator were specifically compared on two ~600 MHz spectrometers. The dual resonator structure 200 was installed on a spectrometer at the field of 599.294 MHz and the standard coil resonator was installed on a spectrometer with a field strength of 598.699 MHz to obtain the NMR spectrum plots 600 and 605. It is to be noted that SNR does not depend to any significant extent on the small difference in frequency between the spectrometers used for these measurements. Further, the inventors validated that the receiver noise figures and other performance parameters were identical between the two spectrometers.

Comparing the peaks of the NMR spectrum plots 600 and 605, it may be seen that the NMR spectrum plot 605 corresponding to the dual resonator structure 200 has a 30% higher peak than the NMR spectrum plot 600 corresponding to the standard coil resonator. The higher peak is indicative of a higher SNR, because the spectra were plotted with the same noise level. Thus, the dual resonator structure 200 has a higher SNR, and therefore clearer and more reliable signal, than the standard coil resonator.

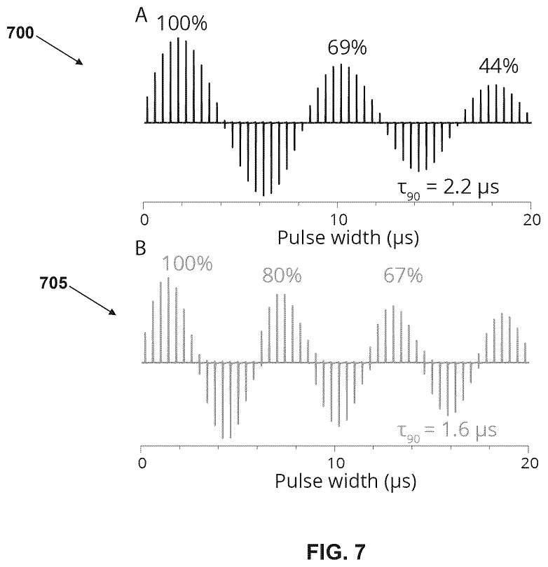

Referring to FIG. 7, example pulse width waveforms 700 and 705 are shown, in accordance with some embodiments of the present disclosure. The pulse width waveforms 700 and 705 compare the homogeneity of the magnetic field produced by the RF pulse (B₁ field). A higher homogeneity of the magnetic field is desired. The pulse width waveform 700 measures the homogeneity of the magnetic field using the standard coil resonator, while the pulse width waveform 705 measures the homogeneity of the dual resonator structure 200. Higher peaks in the pulse width arrays indicate higher homogeneity.

The pulse width waveforms 700 and 705 were determined by measuring the nutation of the first (¹H) channel. The nutation curve on a TKS sample spinning in a 1.6 mm at 35.714 kHz shows a 1450 of ~80% and an 1810 of ~67% for the dual resonator structure 200 (e.g., in the pulse width waveform 705). This is in comparison to the standard coil resonator which has a significantly lower I₄₅₀ of ~69% and 1810 of ~44% shown in the pulse width waveform 700. Thus, the dual resonator structure 200 provides improved homogeneity of the B₁ field.

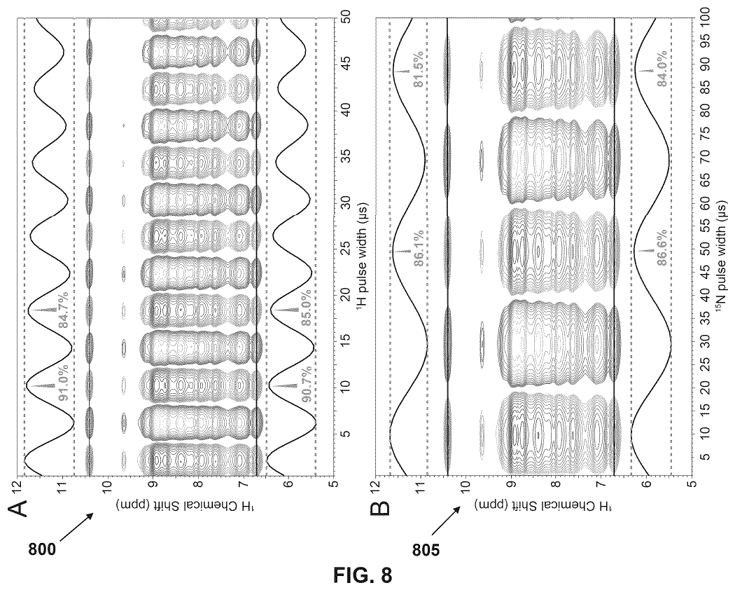

Referring to FIG. 8, example nutation arrays 800 and 805 are shown, in accordance with some embodiments of the present disclosure. The nutation arrays 800 and 805 quantify improvements to SNR on a model biological system, the protein GB1 prepared as a microcrystalline slurry. Due to the nature of the dual resonator structure 200, the X and Y channels (e.g., the outer coil 305) are on the outside of the main ¹H coil (e.g., the inner coil 300). Pulse widths were calibrated to be ~10 μs for ¹⁵N and 5 μs for ¹³C. This power availability consideration on the X and Y channels makes lower power double quantum cross polarization conditions an attractive approach for the dual resonator structure 200. To demonstrate the homogeneity of both ¹H and X and Y coils in the dual resonator structure 200, coil images were collected on GB1 for both ¹H and ¹⁵N using a hNH double cross polarization experiment. The nutation curves of these coil images are plotted in the nutation arrays 800 and 805. The nutation array 800 corresponds to the first (¹H) channel and the nutation array 805 corresponds to the X and Y channels. The nutation arrays 800 and 805 demonstrate outstanding homogeneity of both the inner coil 300 (e.g., the first (¹H) channel) and outer coil 305 (e.g., the X and Y channels), respectively.

Thus, the dual resonator structure provides a separation of high and low frequency circuits to maximize ¹H coil performance. The dual resonator structure provides a proton detection SNR improvement of up to 2-fold higher. Greater increase in SNR is achieved at higher field strength relative to standard coil resonator having a single coil. The dual resonator structure provides better B₁ homogeneity for all channels, including the first (¹H) from the inner coil 300 and X and Y (¹³C and ¹⁵N) from the outer coil 305.

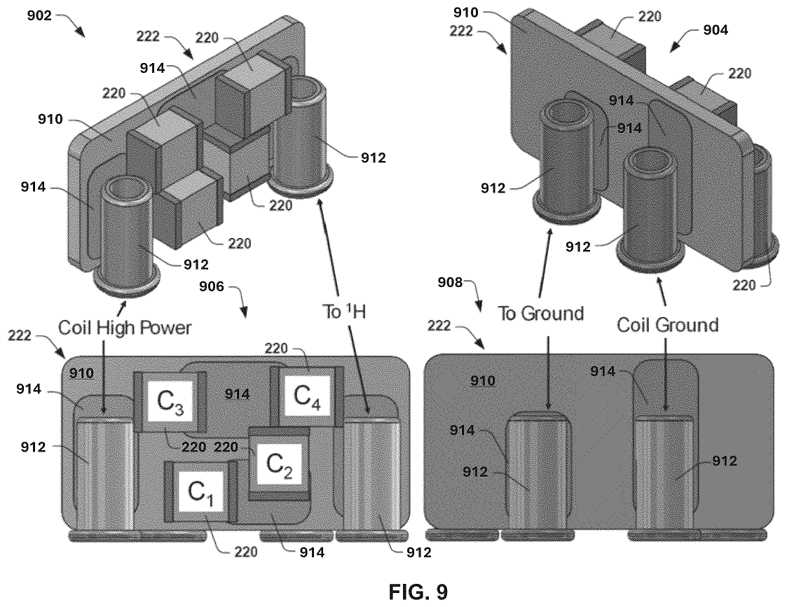

Referring to FIG. 9, an example of a plug-in module 222 for tuning at least the first (¹H) channel of the dual resonator structure, in accordance with some examples of the present disclosure is shown. In order to provide for such an improved performance of the dual resonator structure 200 at such high frequencies, the use of the plug-in module 222 to attach the capacitors 220 can provide for significant benefits. The plug-in module 222 is demonstrated in greater detail in the example of FIG. 9. The plug-in module 222 is demonstrated in the example of FIG. 9 in a first perspective view 902 and a second perspective view 904 showing the opposite side of the plug-in module 222. The example of FIG. 9 also demonstrates a first plan view 906 of the side demonstrated in the first perspective view 902 and a second plan view 908 of the side demonstrated in the second perspective view 904. As an example, the plug-in module 222 can be a modular fabricated circuit, and can be one of a plurality of plug-in modules that can be implemented interchangeably in the probe 145 in NMR spectroscopy experiments. The geometric layout of the plug-in module reduces parasitic inductance and capacitance by minimizing the conductor loop area, controlling trace impedance through predetermined trace widths and spacing, and eliminating leads that introduce stray inductance. At frequencies exceeding 1 GHz, these parasitic effects can materially degrade resonator Q-factor and impedance match.

The plug-in module 222 includes the four capacitors 220, demonstrated as C1, C2, C3, and C4, as corresponding to the respective capacitors 410 in the example of FIG. 4B. The capacitors 220 are fixed to a circuit board substrate 910 that is formed from a dielectric material that is selected based on a specific desired dielectric constant. The capacitors 220 are coupled to each other and/or to conductive receptacles 912 via plate conductors 914 operating as conductive traces that are patterned or formed on the circuit board substrate 910. The capacitors 220 can have predetermined capacitance values selected based on desired performance characteristics of the tuning circuit (e.g., for tuning to a specific frequency or frequency range).

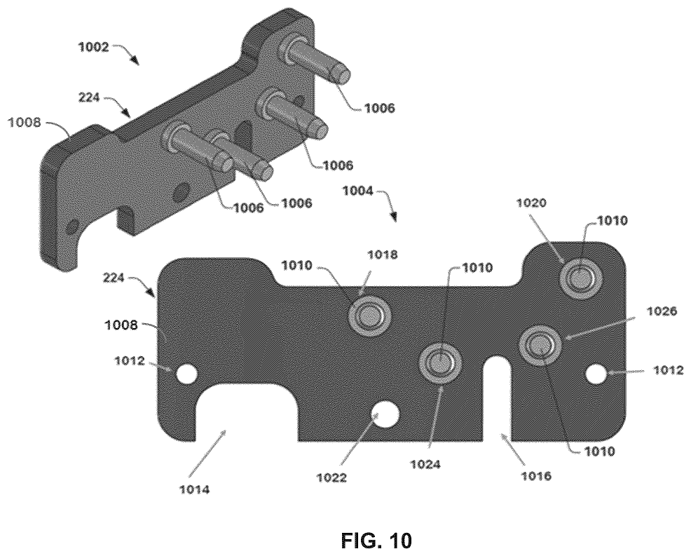

With further reference to FIG. 10, the plug-in board 224 onto which the plug-in module 222 is plugged is shown. The embodiment shown in FIG. 10 demonstrates a perspective view 1002 and a plan view 1004 of the plug-in board 224.

The plug-in board 224 includes conductive mating posts 1006 formed into and extending from a dielectric circuit board substrate 1008. The plug-in board 224 also includes conductive tabs 1010 that extend through the dielectric circuit board substrates 1008 in electrical connection with the conductive mating posts 1006 (e.g., are unitary material with each other). The conductive tabs 1010 facilitate wire connections to the dual resonator structure 200, demonstrated as a coupling to the transmission line of the tune tube assembly 415, to the ¹H channel, and to ground. Particularly, the conductive mating posts 1006 and conductive tabs 1010 can correspond respectively to the nodes 412, 414, 416, and 418 in the example of FIG. 4B. The plug-in board 224 also includes mechanical cutout as physical channels (e.g., for the ¹H channel and for Y high power) and through-holes to receive screws to fasten the plug-in board 224 to the probe 145.

With reference to FIGS. 9 and 10, the conductive receptacles 912 can be designed to receive conductive mating posts 1006 associated with and extending from the plug-in board 224. For example, the conductive receptacles 912 can be press-fit over the conductive mating posts 1006. Therefore, the conductive receptacles 912 can facilitate conductive connections of the nodes 412, 414, 416, and 418 in the example of FIG. 4B to the capacitors C1 through C4. Particularly, based on the press-fit conductive coupling of the conductive receptacles 912 to the conductive mating posts 1006, the conductive receptacles 912 can correspond respectively to the nodes 412, 414, 416, and 418 in the example of FIG. 4B.

As an example, the plug-in module 222 can be plugged into the plug-in board 224 by fitting the plug-in module 222 over the conductive mating posts 1006 and pressing the plug-in module 222 such that each of the conductive mating posts 1006 are received in a respective one of the conductive receptacles 912 to allow a press-fit connection for electrical connectivity between the conductive receptacles 912 and the conductive mating posts 1006. While the conductive mating posts 1006 are cylindrical in the example of FIG. 10, other geometric shapes can instead be implemented for the conductive mating posts 1006 and the accompanying internal surface of the conductive receptacles 912. FIG. 10 additionally includes screw holes 1012. The cutouts include a first cutout 1014 for ¹H and a second cutout 1016 for Y high power. The conductive tabs 1010 provide a first connection 1018 to ¹H, a second connection 1020 to coil high power on plug-in, a third connection 1022 from ground, a fourth connection 1024 to ground, and a fifth connection 1026 to coil ground on plugin.

The physical layout of the capacitors 220, the material choices for the conductive receptacles, the plate conductors 914, and the dielectric material of the circuit board substrate 910, as well as the dimensions and physical spacing between the components on the plug-in module 222 can result in mitigation of parasitic behaviors that may have deleterious effects on the operation of the tuning circuit, and thus the tuning of the resonator. Accordingly, by fabricating the plug-in module 222 as having fixed dimensions, as having static electrical connections between the capacitors 220 and the conductive receptacles 912 (e.g., via the plate conductors 914), and as having a specific geometric layout, the tuning circuit of the plug-in module 222 can provide operational benefits that are superior to traditional loose wiring and solder connections of bulk capacitors for use in a tuning circuit to tune the frequency of the NMR resonator.

As described above, the capacitors 220 can have predetermined capacitance values. However, circuit device manufacturers typically incorporate a tolerance in capacitance values of commercial capacitor devices, thus resulting in unpredictable performance characteristics of a conventionally wired tuning circuit. Pre-experiment testing of a conventionally wired tuning circuit could provide for determination of the circuit characteristics of the tuning circuit, but failure to meet sufficient operational requirements could result in significant time loss from having to disconnect and rewire a new tuning circuit. Alternatively, individual capacitors could be tested, but such individual testing would be time consuming, onerous, and would not provide an accurate demonstration of the operational characteristics of the entire tuning circuit (e.g., including connection losses that may affect impedance).

However, because multiple plug-in modules 222 can be bulk fabricated as modular units, each of the plug-in modules 222 can be bench-tested after fabrication to provide an accurate determination of the circuit characteristics of the tuning circuit thereon. Each plug-in module 222 can thus provide precise and repeatable performance characteristics upon being plugged into the plug-in board 224 on the probe 145. If a given one of the plug-in modules 222 having a same set of capacitors 220 (e.g., same capacitor values for the capacitors 220) is determined to have circuit characteristics that are outside of a predefined operational specification, the respective plug-in module 222 can merely be discarded or repurposed and replaced by a plug-in module 222 determined to operate within specification. Accordingly, significant time can be saved in preparing a specific tuning circuit for a specific NMR experiment by plugging a plug-in module 222 having known operational characteristics into the plug-in board 224, as opposed to the extensive duration of time spent wiring and soldering bulk capacitors to the probe 145 in a conventional manner that could result in unpredictable and undesirable operational characteristics.

As used herein, the term “mount” includes join, unite, connect, couple, associate, insert, hang, hold, affix, attach, fasten, bind, paste, secure, bolt, screw, rivet, solder, weld, glue, form over, form in, layer, mold, rest on, rest against, etch, abut, and other like terms. The phrases “mounted on”, “mounted to”, and equivalent phrases indicate any interior or exterior portion of the element referenced. These phrases also encompass direct mounting (in which the referenced elements are in direct contact) and indirect mounting (in which the referenced elements are not in direct contact but are connected through an intermediate element). Elements referenced as mounted to each other herein may further be integrally formed together, for example, using a molding or a thermoforming process as understood by a person of skill in the art. As a result, elements described herein as being mounted to each other need not be discrete structural elements. The elements may be mounted permanently, removably, or releasably unless specified otherwise.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”. Still further, using “and” or “or” in the detailed description is intended to include “and/or” unless specifically indicated otherwise. The illustrative embodiments may be implemented as a method, apparatus, or article of manufacture using standard programming and/or engineering techniques to produce software, firmware, hardware, or any combination thereof to control a computer to implement the disclosed embodiments.

Any directional references used herein, such as left-side, right-side, top, bottom, back, front, up, down, above, below, etc., are for illustration only based on the orientation in the drawings selected to describe the illustrative embodiments.

The foregoing description of illustrative embodiments of the disclosed subject matter has been presented for purposes of illustration and of description. It is not intended to be exhaustive or to limit the disclosed subject matter to the precise form disclosed, and modifications and variations are possible in light of the above teachings or may be acquired from practice of the disclosed subject matter. The embodiments were chosen and described in order to explain the principles of the disclosed subject matter and as practical applications of the disclosed subject matter to enable one skilled in the art to utilize the disclosed subject matter in various embodiments and with various modifications as suited to the particular use contemplated.

1. A dual resonator structure for a nuclear magnetic resonance (NMR) probe, the dual resonator structure comprising:
an inner coil comprising a solenoid coil; and
an outer coil comprising a saddle coil,
wherein the inner coil is configured to tune a first channel to a first frequency;
wherein the outer coil is configured to tune X and Y channels to second and third frequencies independent from and simultaneously with the first frequency;
wherein the outer coil is radially spaced from the inner coil; and
wherein the outer coil and the inner coil are configured to produce orthogonal magnetic fields.

2. The dual resonator structure of claim 1, wherein the first channel is at least one of an ¹H (hydrogen/proton) channel or a ¹⁹F (fluorine) channel.

3. The dual resonator structure of claim 2, wherein the first frequency is greater than or equal to approximately 550 MHz.

4. (canceled)

5. The dual resonator structure of claim 1, wherein each of the inner coil and the outer coil is made of a susceptibility matched wire.

6. The dual resonator structure of claim 5, wherein the inner coil is formed from a first material and the outer coil is formed from a second material.

7. The dual resonator structure of claim 6, wherein the first material is different from the second material.

8. The dual resonator structure of claim 5, wherein at least one of inner coil or the outer coil are formed from a core, an extrusion disposed over the core, and a plating disposed over the extrusion.

9. The dual resonator structure of claim 1, wherein the outer coil comprises:
a first saddle portion positioned on a first side of the inner coil; and
a second saddle portion positioned on a second side of the inner coil, the second side of the inner coil opposite the first side of the inner coil,
wherein the first saddle portion and the second saddle portion have a crossed portion on a third side of the inner coil, and
wherein the first saddle portion and the second saddle portion are spaced from one another proximate a fourth side of the inner coil to define an opening that is opposite the third side of the inner coil.

10. The dual resonator structure of claim 9, wherein the first saddle portion extends about a first arcuate path approximately concentric with the first side of the inner coil; and
the second saddle portion extends about a second arcuate path approximately concentric the second side of the inner coil.

11. The dual resonator structure of claim 1, wherein the inner coil is electrically connected to one or more capacitors to tune the first channel to the first frequency.

12. (canceled)

13. (canceled)

14. The dual resonator structure of claim 1, wherein the solenoid coil comprises:
a first end;
a second end longitudinally spaced from the first end, defining a length therebetween; and
a plurality of turns disposed at a predetermined pitch along the length, the plurality of turns defining a diameter of the solenoid coil.

15. The dual resonator structure of claim 14, wherein the outer coil comprises a length parallel and equal to the length of the inner coil and the outer coil comprises a height greater than the diameter of the inner coil.

16. (canceled)

17. (canceled)

18. The dual resonator structure of claim 14, wherein the predetermined pitch is variable along the length.

19. (canceled)

20. (canceled)

21. The dual resonator structure of claim 1, wherein the first channel comprises at least one of ¹H nuclei or ¹⁹F nuclei; and the X and Y channels comprise at least one of ¹³C or ¹⁵N nuclei.

22. The dual resonator structure of claim 1, wherein the solenoid coil of the inner coil is formed from at least two co-wound solenoid coils.

23. The dual resonator structure of claim 1, wherein the dual resonator structure is disposed at a distal end of a nuclear magnetic resonance (NMR) probe.

24-51. (canceled)

52. A plug-in module for a nuclear magnetic resonance (NMR) probe, the plug-in module comprising:
a circuit board substrate;
a plurality of capacitors fixed to the circuit board substrate, the capacitors forming a tuning circuit that cooperates with a solenoid of a resonator structure of the NMR probe to form a resonant circuit associate with operation of the NMR probe;
a plurality of conductive receptacles configured to conductively couple with a plug-in board that is mechanically coupled to the NMR probe and that is conductively coupled to the resonator structure and to a transceiver; and
a plurality of plate conductor interconnects configured to provide electrical connectivity between the capacitors and the conductive receptacles in a predefined arrangement of the tuning circuit.

53-57. (canceled)

58. A nuclear magnetic resonance (NMR) probe system comprising:
an NMR probe comprising a resonator structure;
a radio frequency (RF) transceiver configured to generate a tuning signal; and
a plug-in board coupled to the NMR probe, the plug-in board comprising a plurality of conductors that are wired respectively to the resonator structure and to the RF transceiver, the conductors being configured to receive an electrical connection of conductive receptacles associated with a plug-in module comprising a plurality of capacitors configured to form a tuning circuit, such that mechanical plug-in of the conductors of the plug-in board with the conductive receptacles of the plug-in module provides electrical connectivity between the tuning circuit and the resonator structure to form a resonator circuit with respect to the tuning signal.

59. The NMR probe system of claim 58, wherein the resonator structure is a dual resonator structure.

60. The NMR probe system of claim 59, wherein the dual resonator structure comprises an inner coil and an outer coil, the outer coil radially spaced from the inner coil.

61. The NMR probe system of claim 60, wherein the inner coil comprises a solenoid coil.

62. The NMR probe system of claim 60, wherein the outer coil comprises a saddle coil.

63. The NMR probe system of claim 62, wherein the saddle coil comprises a first saddle portion disposed along a first side of a solenoid coil and a second saddle portion disposed along a second side of the solenoid coil, the second side opposite the first side.
